(19) United States
(12) Patent Application Publication
(10) Pub. No.: US 2004/0097102 A1
(43) Pub. Date: May 20, 2004

(54) Annealed wafer and manufacturing method thereof

(76) Inventors: Young-Hee Mun, Gumi-city (KR); Gun Kim, Gumi-city (KR); Sung-Ho Yoon, Gumi-city (KR)

Correspondence Address: JACOBSON HOLMAN PLLC, 400 SEVENTH STREET N.W., SUITE 600, WASHINGTON, DC, 20004, US

(21) Appl. No.: 10/325,862

(22) Filed: Dec. 23, 2002

(30) Foreign Application Priority Data
Nov. 19, 2002 (KR) 2002-72003

(51) Int. Cl. H01L 21/336; H01L 21/26; H01L 21/324; H01L 21/42; H01L 21/477

(52) U.S. Cl. 438/795

(57) ABSTRACT

An annealed wafer and manufacturing method thereof for producing a high quality annealed wafer free from slip defects despite high temperature annealing carried out on the silicon wafer to form a high density oxygen defect layer in the bulk of the silicon wafer as well as a denuded zone of a device active region by removing grown-in defects. The method invention includes the steps of preheating a silicon wafer loaded in an annealing furnace at a temperature of about 500° C., with the silicon wafer having an initial oxygen concentration of 11˜14 ppma; raising the temperature to at least 1,100° C. at a temperature rise rate of 1˜14° C./min by setting an ambience inside the annealing furnace as an inert gas including H₂ or Ar, a mixed gas of H₂ and Ar, or the like; maintaining the temperature of at least 1,100° C. for a predetermined time to carry out annealing; and dropping the temperature to about 500° C. at a temperature drop rate of 1˜14° C./min.

### BACKGROUND OF THE INVENTION

1. Field of the Invention

The present invention relates to an annealed wafer and, more particularly, to an annealed wafer and manufacturing method thereof for preventing the generation of slips during manufacturing of the annealed wafer.

2. Background of the Related Art

Generally, a silicon wafer is prepared by growing a single crystalline silicon ingot and forming a wafer form through slicing, etching, and polishing processes carried out on the single crystalline silicon ingot. Grown-in defects generated from growing the single crystalline silicon are eliminated from the silicon wafer in order to provide a device active region that is free of defects as well as form a highly concentrated oxygen defect layer in the bulk of the silicon wafer, for which annealing is essentially carried out at high temperature.

A method of manufacturing an annealed wafer according to a related art, as shown in FIG. 1A, includes a step 1 of preheating a silicon wafer loaded in an annealing furnace at a temperature of about 500° C.; a step II of raising the temperature to about 1,100° C. by setting an ambience inside the annealing furnace as an inert gas including H₂ or Ar, a mixed gas of H₂ and Ar, or the like; a step III of raising the temperature to at least 1,100° C., i.e., about 1,200° C., to maintain for a predetermined time to carry out annealing; and a step IV of dropping the temperature to about 500° C. In this case, each of the general temperature rise and drop rates is about 30° C./min.

Generally, when a silicon wafer is loaded in an annealing furnace to manufacture an annealed wafer, as shown in FIG. 2, an underside of the silicon wafer W is contacted with upper ends of wafer supports 10 installed inside the annealing furnace. When high temperature annealing is carried out on the silicon wafer W mounted on the wafer supports 10 inside the annealing furnace, thermal imbalance is generated from the surface portion of the silicon wafer W contacted with the wafer supports 10 relative to the other portion of the silicon wafer W not in contact with the wafer supports 10. The heat expansion difference according to the temperature difference brings about plastic deformation, i.e., deformation exceeding the elastic limit due to an external force, such that the initial shape cannot be restored. Hence, slip defects, as shown in FIG. 1B, are inevitable. Namely, the slip defects are generated from the contact areas with the wafer supports 10 as well as the edge area which receives relatively large heat radiation per unit area.

Accordingly, annealed wafers manufactured by the related art method include internal slip defects which degrade the characteristics of the associated semiconductor device.

### SUMMARY OF THE INVENTION

Accordingly, the present invention is directed to an annealed wafer and manufacturing method thereof that substantially obviates one or more of the problems due to limitations and disadvantages of the related art.

The object of the present invention is to provide an annealed wafer and manufacturing method thereof that provides a high quality annealed wafer free from slip defects despite high temperature annealing carried out on the silicon wafer, to form a high density oxygen defect layer in the bulk of the silicon wafer as well as a denuded zone of a device active region by removing grown-in defects.

To achieve these and other advantages, and in accordance with the purpose of the present invention as embodied and broadly described herein, a method of manufacturing an annealed wafer according to the present invention includes the steps of preheating a silicon wafer loaded in an annealing furnace at a temperature of about 500° C., wherein the silicon wafer has an initial oxygen concentration of 11˜14 ppma; raising the temperature to at least 1,100° C. at a temperature rise rate of 1˜14° C./min by setting an ambience inside the annealing furnace as an inert gas including H₂ or Ar, a mixed gas of H₂ and Ar, or the like; maintaining the temperature of at least 1,100° C. for a predetermined time to carry out annealing; and dropping the temperature to about 500° C. at a temperature drop rate of 114° C./min.

Preferably, the temperature rise and drop rates are maintained as 1° C./min−7° C./min over a temperature range of 50° C.−1,100° C.

In another aspect of the present invention, an annealed wafer manufactured by the above-described method has no slip defect over an edge thereof.

In a further aspect of the present invention, an annealed wafer manufactured by the above-described method has no slip defect at an entire surface thereof.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1A illustrates a graph of annealing temperature in a method of manufacturing an annealed wafer according to a related art;

FIG. 1B illustrates a surface picture of an annealed wafer manufactured by the method according to the related art;

FIG. 2 illustrates a diagram of a silicon wafer mounting device in an annealing furnace according to the related art;

FIG. 3 illustrates a B-type slip picture of an annealed wafer according to rates of temperature rise and drop when an initial oxygen concentration of a silicon wafer is 11 ppma;

FIG. 4 illustrates a B-type slip picture of an annealed wafer according to rates of temperature rise and drop when an initial oxygen concentration of a silicon wafer is 12 ppma;

FIG. 5 illustrates a B-type slip picture of an annealed wafer according to rates of temperature rise and drop when an initial oxygen concentration of a silicon wafer is 13 ppma;

FIG. 6 illustrates a B-type slip picture of an annealed wafer according to rates of temperature rise and drop when an initial oxygen concentration of a silicon wafer is 14 ppma;

FIG. 7 illustrates an A-type slip picture of an annealed wafer according to rates of temperature rise and drop when an initial oxygen concentration of a silicon wafer is 11 ppma;

FIG. 8 illustrates an A-type slip picture of an annealed wafer according to rates of temperature rise and drop when an initial oxygen concentration of a silicon wafer is 12 ppma;

FIG. 9 illustrates an A-type slip picture of an annealed wafer according to rates of temperature rise and drop when an initial oxygen concentration of a silicon wafer is 13 ppma;

FIG. 10 illustrates an A-type slip picture of an annealed wafer according to rates of temperature rise and drop when an initial oxygen concentration of a silicon wafer is 14 ppma; and

FIG. 11 illustrates a graph of annealing temperature in a method of manufacturing an annealed wafer according to the present invention.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

### DETAILED DESCRIPTION OF THE PREFERRED EMBODIMENTS

Reference will now be made in detail to the preferred embodiments of the present invention, examples of which are illustrated in the accompanying drawings. Where possible, the same reference numerals will be used to illustrate like elements throughout the specification.

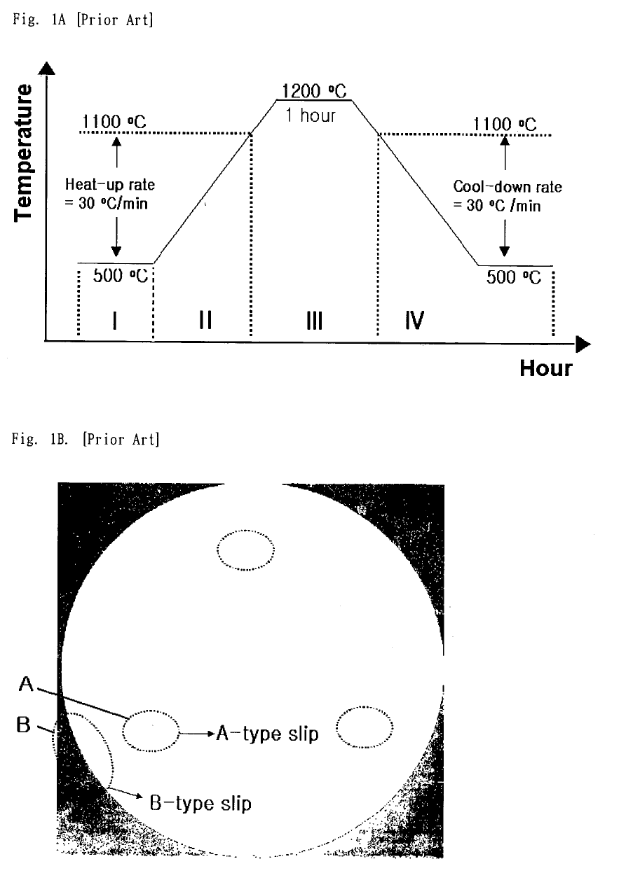

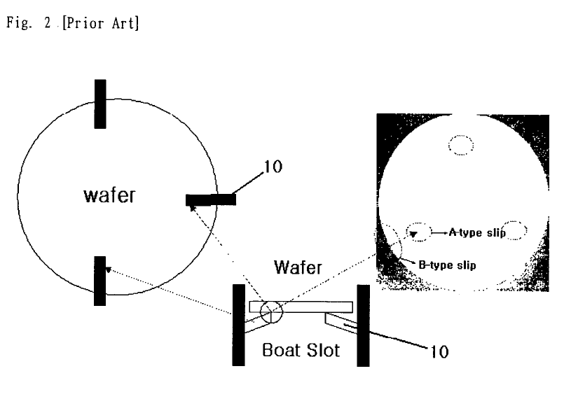

For the detailed explanation of the present invention, the slip defects generated on the wafer W in FIG. 1B are classified into two types according to their generated parts. Namely, a slip generated from an edge of the annealed wafer W is defined as a B-type slip defect and a slip generated from a portion inside the annealed wafer W contacted with the end of the wafer support 10 is defined as an A-type slip defect.

In the process of carrying out annealing on the silicon wafer at high temperature, the slip defects, as mentioned in the foregoing explanation of the related art, are generated as a result of the contact areas with the wafer supports 10, as well as the edge area receiving relatively large heat radiation per unit area. The slip defects arise due to the thermal imbalances which are generated between those portions of the underside of the silicon wafer W contacted with the wafer supports 10 and those portions of the silicon wafer W not in contact with the wafer supports 10, as well as from the edge area. Hence, the heat expansion difference according to the temperature difference brings about the plastic deformation. And, when the silicon wafer is annealed at high temperature, the slip defects are initially generated like points from the contact spots with the wafer supports 10 as well as the edge area, which again receives relatively large heat radiation per unit area. A phenomenon of ‘moving’, that namely the initial points of slip defects extend linearly in one direction, occurs while the annealing proceeds, whereby the slip defects grow on the surface of the silicon wafer W.

In this case, the ‘moving’ of the slip defects is inhibited by oxygen precipitate generated from annealing of the silicon wafer. Namely, a product amount of the oxygen precipitate increases in proportion to an initial oxygen concentration in the silicon wafer when the silicon wafer is annealed at the high temperature. It is known that the oxygen precipitate prevents the ‘moving’ of the slip defects, and such an effect (effect that oxygen precipitate suppresses dislocation, i.e., ‘moving’, of slips) is called ‘dislocation pinning effect’. In this case, the initial oxygen concentration of the silicon wafer is a value determined by a concentration of oxygen contained in a single crystalline silicon ingot during formation thereof for manufacturing of the silicon wafer.

Considering that the slip defects generated from manufacturing the annealed wafer are brought about in accordance with the plastic deformation of the silicon wafer W due to the thermal imbalance between the predetermined portions of the silicon wafer W, the slip defects can be inhibited or eliminated by minimizing the thermal imbalance in the silicon wafer during high temperature annealing of the silicon wafer W. Considering that ‘dislocation pinning effect’ due to the oxygen precipitate can be achieved if the initial oxygen concentration of the silicon wafer W is high, the present invention provides a scheme for suppressing or eliminating slip defects when the initial oxygen concentration of the silicon wafer is in the range of 11 ppma˜14 ppma.

When the initial oxygen concentration of the silicon wafer is 11 ppma˜14 ppma, thermal imbalance occurs upon high temperature annealing of the silicon wafer W. In order to find rates of temperature rise and drop to prevent the slip defects from occurring on the silicon wafer, the following experiments were carried out.

Namely, silicon wafers having initial oxygen concentrations of 11 ppma, 12 ppma, 13 ppma, and 14 ppma were heated to 1,100° C. from 500° C. at temperature change rates of 7° C/min, 14° C./min, 21° C./min, and 28° C./min, respectively. Subsequently, the silicon wafers were heated to 1,200° C. from 1,100° C. at a temperature rise rate of 4° C./min and were then maintained for a predetermined time for annealing. Thereafter, the temperatures of the silicon wafers were reduced to 500° C. at the same change, that is, at the same change rate of heating from 500° C. to 1,100° C., respectively. It was then checked whether slip defects were generated on the silicon wafers.

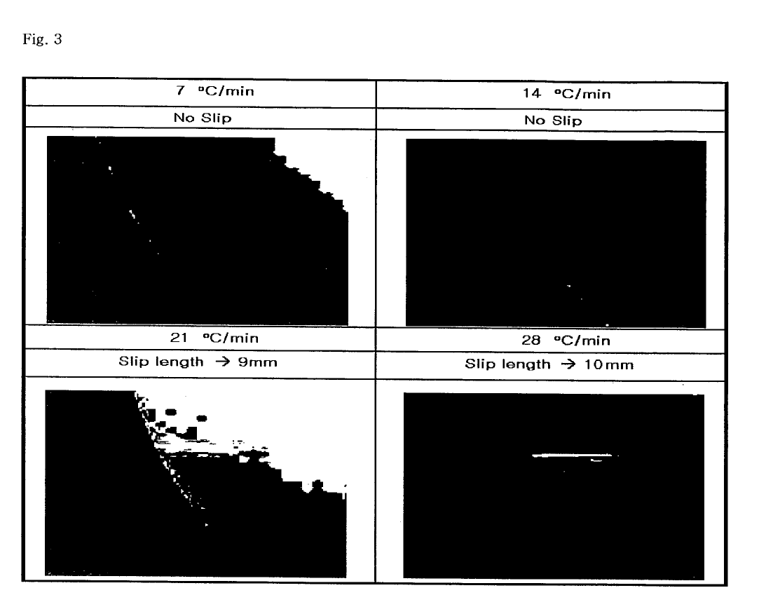

Sizes of the slip defects that occurred according to various the initial oxygen concentrations and the various temperatures rise/drop rates of the silicon wafers are shown in Table 1 (size of B-type slip defect) and Table 2 (size of A-type slip defect). Pictures of the slip defects of the annealed wafers illustrating the results summarized in Table 1 and Table 2 are shown in FIGS. 3 to 10.

TABLE 1
Size of B-type slip defect

| | 7° C./min | 14° C./min | 21° C./min | 28° C./min |
|---|---|---|---|---|
| 11 ppma | 0 | 0 | 9 mm | 10 mm |
| 12 ppma | 0 | 0 | 10 mm | 13 mm |
| 13 ppma | 0 | 0 | 7 mm | 8 mm |
| 14 ppma | 0 | 0 | 9 mm | 8 mm |

TABLE 2
Size of A-type slip defect

| | 7° C./min | 14° C./min | 21° C./min | 28° C./min |
|---|---|---|---|---|
| 11 ppma | 1 mm (point) | 5 mm | 17 mm | 23 mm |
| 12 ppma | 1 mm (point) | 4 mm | 12 mm | 19 mm |
| 13 ppma | 1 mm (point) | 2 mm | 6 mm | 11 mm |
| 14 ppma | 1 mm (point) | 1 mm | 5 mm | 7 mm |

Whether the A-type and B-type slip defects were generated according to the initial oxygen concentrations and temperature rise/drop rates of the silicon wafers is explained in detail by referring to Table 1, Table 2, and FIGS. 3 to 10 as follows.

First of all, looking at the B-type slip defects generated from the edges of the annealed wafers, the B-type slip defects fail to occur if the temperature rise/drop rates are equal to or less than 14° C./min within the entire range of 11 ppma˜14 ppma, while slip averaging defects about 10 mm long occur at the respective initial oxygen concentrations of the silicon wafers if the temperature rise/drop rates are 21° C./min and 28° C./min. Therefore, the temperature change rates equal to or less then 14° C./min represent critical ranges that produce a new result, namely the generation of an annealed wafer that lacks B-type slip defects.

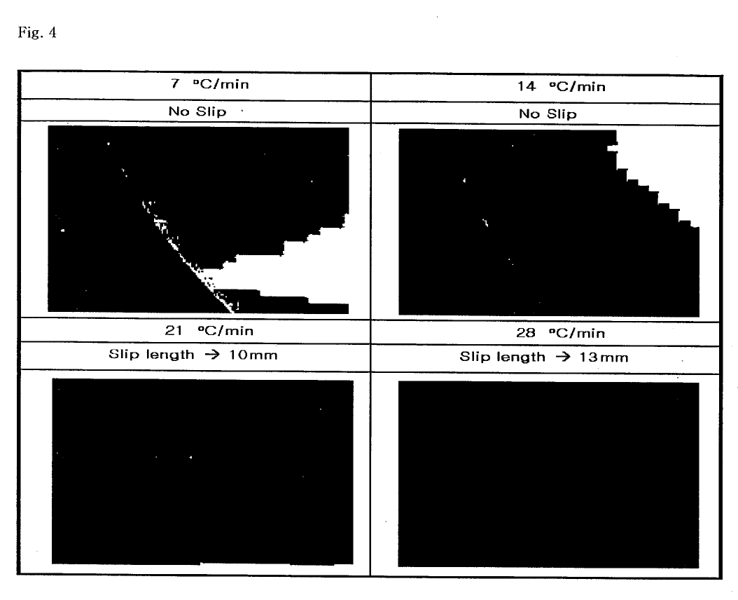

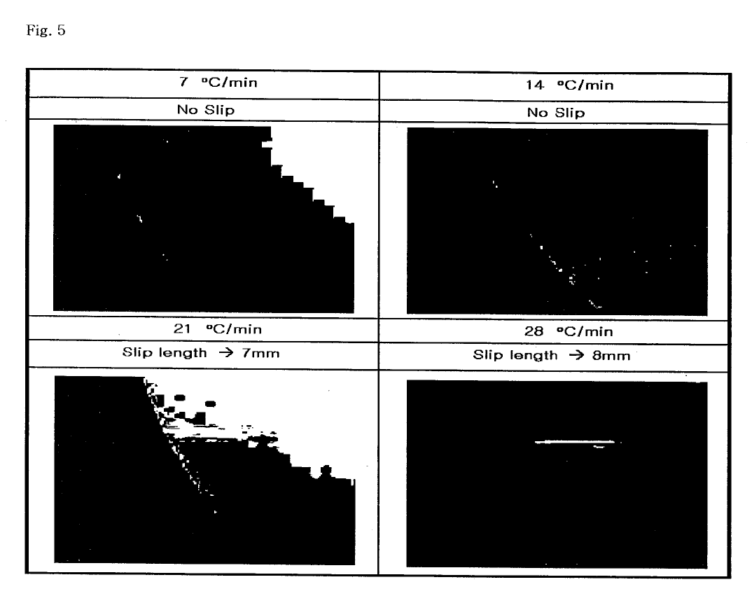

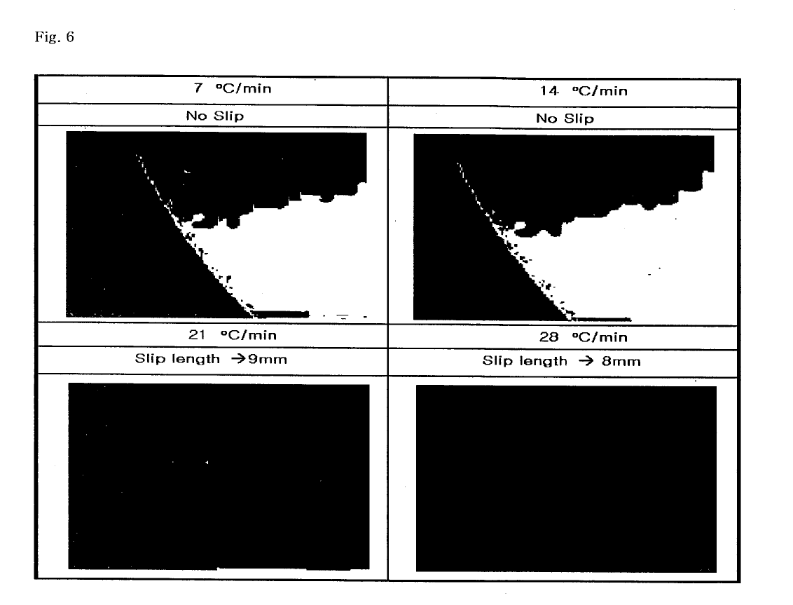

The B-type slip defects of the silicon wafers having 11 ppma of the initial oxygen concentration according to the respective temperature rise/drop rates are shown in FIG. 3. The B-type slip defects of the silicon wafers having 12 ppma of the initial oxygen concentration according to the respective temperature rise/drop rates are shown in FIG. 4. The B-type slip defects of the silicon wafers having 13 ppma of the initial oxygen concentration according to the respective temperature rise/drop rates are shown in FIG. 5. And, the B-type slip defects of the silicon wafers having 14 ppma of the initial oxygen concentration according to the respective temperature rise/drop rates are shown in FIG. 6.

Hence, the B-type slip defects at the edges of the annealed wafers fail to occur if the temperature rise/drop rates are equal to or less than 14° C./min on high temperature annealing of the silicon wafers. Namely, when the annealed wafer is manufactured by annealing the silicon wafer at high temperature, the temperature rise/drop rates may be controlled to be equal to or less than 14° C./min to eliminate the generation of B-type slip defects by preventing the plastic deformation that occurs at the edge of the silicon wafer due to thermal imbalance when temperature rise and fall rates are greater than 14° C./min.

Meanwhile, looking at the A-type slip defects occurring at the contact portions with the ends of the wafer supports 10 of the annealed wafers W, as shown in Table 2, the size of the slip defect increases as the temperature rise/drop rate increases at the same initial oxygen concentration of the silicon wafer. This is because the thermal imbalance in the silicon wafer increases as the temperature rise/drop rate increases.

When the initial oxygen concentration of the silicon wafer lies between 11 ppma˜14 ppma, A-type slip defects are generated with a point shape of about 1 mm at a temperature rise/drop rate of 7° C./min so that ‘moving’ fails to occur further. If the temperature rise/drop rate is below 7° C./min, it is expected that the A-type slip defect fails to occur.

As the initial oxygen concentration increases at the same temperature rise/drop rate, the size of the A-type slip defect decreases. This is because of the ‘dislocation pinning effect’ of the oxygen precipitate enhanced by the increment of the initial oxygen concentration of the silicon wafer.

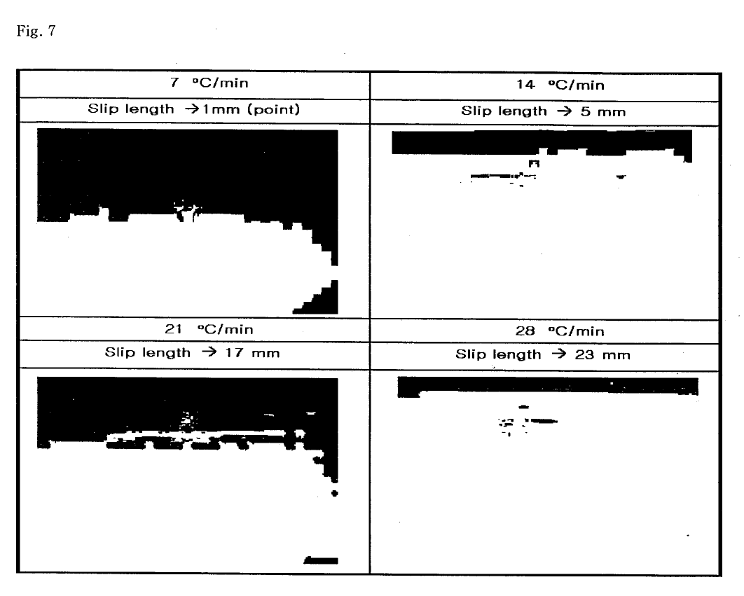

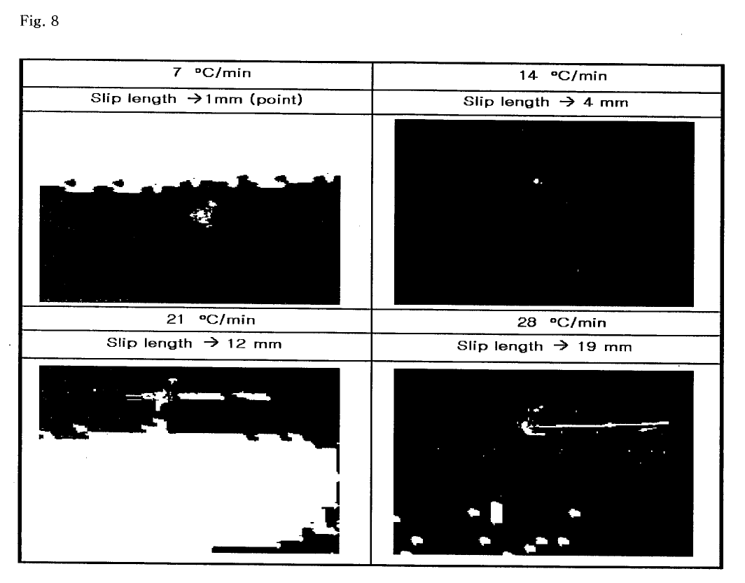

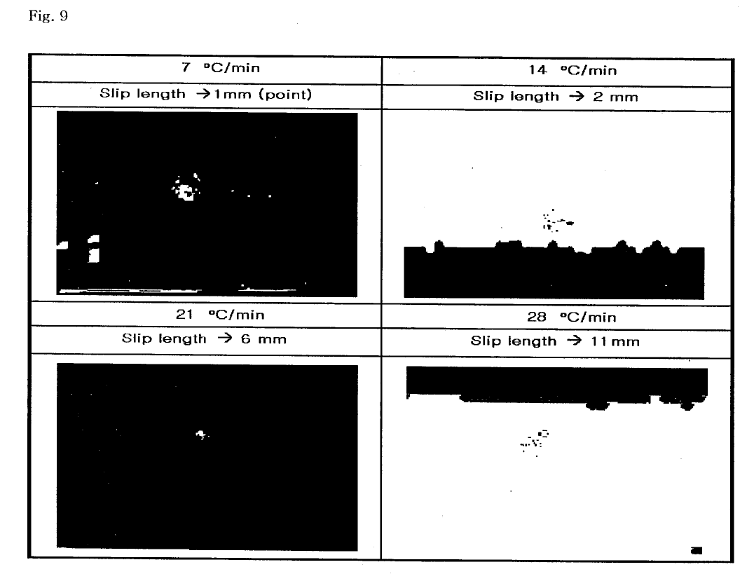

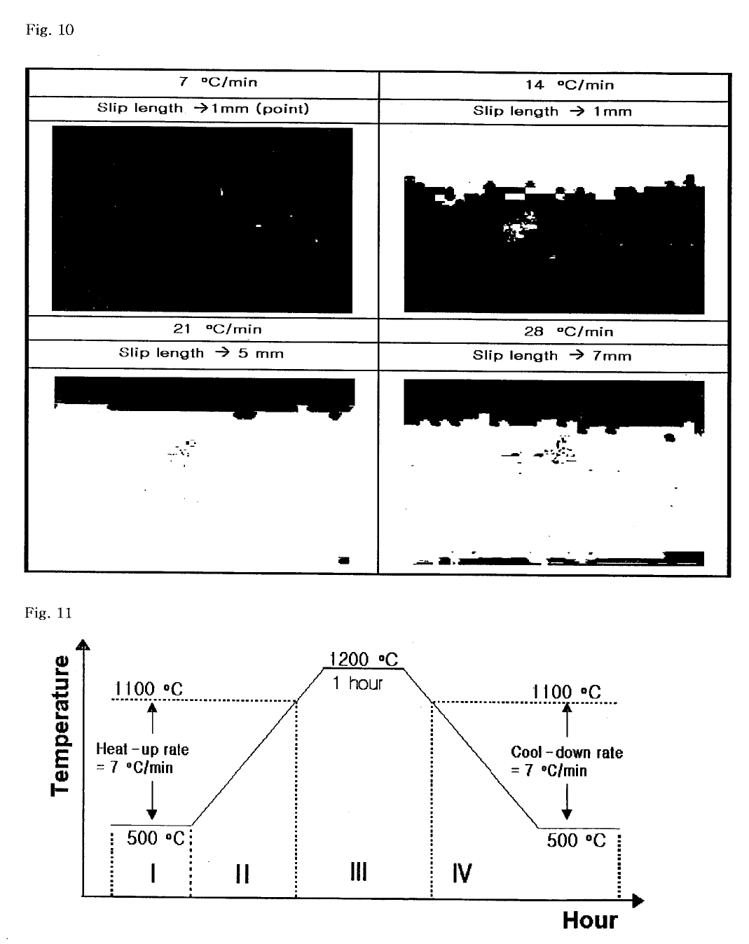

The A-type slip defects of silicon wafers having 11 ppma of the initial oxygen concentration according to the respective temperature rise/drop rates are shown in FIG. 7. The A-type slip defects of the silicon wafers having 12 ppma of the initial oxygen concentration according to the respective temperature rise/drop rates are shown in FIG. 8. The A-type slip defects of the silicon wafers having 13 ppma of the initial oxygen concentration according to the respective temperature rise/drop rates are shown in FIG. 9. And, the A-type slip defects of the silicon wafers having 14 ppma of the initial oxygen concentration according to the respective temperature rise/drop rates are shown in FIG. 10.

Hence, A-type slip defects are generated with a point shape if the temperature rise/drop rate is 7° C./min during high temperature annealing of the silicon wafer. Conversely the A-type slip defect fails to occur if the temperature rise/drop rate is below 7° C./min during high temperature annealing of the silicon wafer. Namely, when the annealed wafer is manufactured by annealing the silicon wafer at high temperature, the temperature rise/drop rate may be controlled to be equal to or less than 7° C./min to suppress or eliminate the generation of A-type slip defects by maintaining the thermal balance between the portion of the silicon wafer W contacted with the end of the wafer support 10 and another inner portion of the silicon wafer W failing to be contacted with the end of the wafer support 10.

Based on the above-described experimental results, an embodiment of the present invention is explained in detail as follows.

FIG. 11 illustrates a graph of annealing temperature in a method of manufacturing an annealed wafer according to the present invention.

Referring to FIG. 11, a method of manufacturing an annealed wafer according to the present invention includes a step I of preheating a silicon wafer loaded in an annealing furnace at a temperature of about 500° C., with the silicon wafer having an initial oxygen concentration of 11˜14 ppma; a step II of raising the temperature to about 1,100° C. at a temperature rise rate of 1˜14° C./min by setting an ambience inside the annealing furnace as an inert gas including H₂ or Ar, a mixed gas of H₂ and Ar, or the like; a step III of raising the temperature to at least 1,100° C., i.e., about 1,200° C., and maintaining such temperature for a predetermined time to carry out annealing; and a step IV of dropping the temperature to about 500° C. at the temperature cool-down rate of 1˜14° C./min. Thus, the present invention enables the manufacture of an annealed wafer without slip defects at the edge area.

In this case, the temperature rises or drops at a temperature change rate equal to or less than 14° C./min over a temperature range of 500° C.-1,100° C., whereby the generation of the B-type slip defect from the edge of the annealed wafer can be suppressed. This mechanism is explained in detail in the foregoing description of Table 1. In the interests of adequate productivity, the temperature change rate for the temperature range of 500° C.-1,100° C. is set to be at least 1° C./min for manufacturing of the annealed wafer.

Moreover, in order to suppress and eliminate the A-type slip defect generated from an inner portion of the annealed wafer, the temperature change rate over the temperature range of 500° C.-1,100° C. is preferably set to be 1˜7° C./min. Namely, the temperature rise/drop rate is set to be equal to or smaller than 7° C./min, thereby making it possible to suppress and eliminate generation of A-type slip defect at the portion of the silicon wafer W contacted with the end of the wafer support 10. This mechanism is explained in detail in the foregoing description of Table 2. In the interests of adequate productivity in annealed wafer manufacturing the temperature rise/drop rate for the temperature range of 500° C.-1,100° C. is set to be at least 1° C./min.

Accordingly, the present invention provides an annealed wafer and manufacturing method thereof enabling the production of a high quality annealed wafer free from slip defects despite high temperature annealing carried out on the silicon wafer to form a high density oxygen defect layer in the bulk of the silicon wafer as well as a denuded zone of a device active region by removing grown-in defects.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method of manufacturing an annealed wafer, comprising the steps of:
preheating a silicon wafer loaded in an annealing furnace at a temperature of about 500° C. wherein the silicon wafer has an initial oxygen concentration of 11˜14 ppma;
raising the temperature to at least 1,100° C. at a temperature rise rate of 1˜14° C./min by setting an ambience inside the annealing furnace as an inert gas including H₂ or Ar, a mixed gas of H₂ and Ar, or the like;
maintaining the temperature of at least 1,100° C. from 1 minute to 60 minutes in order to carry out annealing; and
dropping the temperature to about 500° C. at a temperature drop rate of 1˜14° C./min.

2. The method of claim 1, wherein the temperature rise and drop rates are maintained between 1° C./min−7° C./min over a temperature range of 500° C.-1,100° C.

3. An annealed wafer manufactured by the method of claim 1, the annealed wafer having no slip defect at an edge thereof.

4. An annealed wafer manufactured by the method of claim 2, the annealed wafer having no slip defect over an entire surface thereof.
